(19) United States
(12) Patent Application Publication
(10) Pub. No.: US 2006/0003252 A1
(43) Pub. Date: Jan. 5, 2006

(54) Chemical amplification type silicone based positive photoresist composition

(76) Inventors: Taku Hirayama, Kawasaki-shi (JP); Tomotaka Yamada, Kawasaki-shi (JP); Daisuke Kawana, Kawasaki-shi (JP); Kouki Tamura, Kawasaki-shi (JP); Kazufumi Sato, Kawasaki-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/537,290

(22) PCT Filed: Dec. 1, 2003
(86) PCT No.: PCT/JP03/15344

§ 371 Date: Jun. 22, 2005

(30) Foreign Application Priority Data
Dec. 2, 2002 (JP) 2002-350563
Feb. 24, 2003 (JP) 2003-46611
Jul. 2, 2003 (JP) 2003-190618

(51) Int. Cl. G03F 7/021

(52) U.S. Cl. 430/170; 430/192

(57) ABSTRACT

A chemical-amplification type silicone-based positive-working resist composition that can be prepared from compounds of good availability as the base materials through simple means and can provide a bilayer resist material from which a fine pattern of high resolution, high aspect ratio, desirable cross-sectional profile and low line edge roughness can be formed. In particular, a chemical-amplification type positive-working resist composition comprising an alkali soluble resin (A) and a photoacid generator (B) wherein a ladder-type silicone copolymer comprising (hydroxyphenylalkyl)silsesquioxane units (a₁), (alkoxyphenylalkyl)silsesquioxane units (a₂) and alkyl- or phenylsilsesquioxane units (a₃) is used as the alkali soluble resin (A). The copolymer wherein, in the component (A), the units (a₃) are phenylsilsesquioxane units is a novel compound.

### TECHNOLOGICAL FIELD

The present invention relates to a novel chemical-amplification type silicone-based positive-working photoresist composition, in particular, when used as the upper layer of a bilayered resist material, capable of giving a pattern having little line edge roughness along with high pattern resolution and an excellent cross sectional profile as well as a bilayered resist material using same and a ladder-type silicone copolymer used therein.

### BACKGROUND TECHNOLOGY

Along with the rapid progress in the semiconductor devices toward higher fineness in recent years, it is also required in the photolithographic process used in the manufacture thereof to undertake works with fineness of 0.20 nm or finer and development is now under way for chemical-amplification type resist materials corresponding to radiations having a short wavelength such as KrF, ArF or F₂ excimer laser beams and others.

In conducting photolithographic fine works by using a heretofore known chemical-amplification type resist material, however, it is very difficult to accomplish formation of a pattern having a high aspect ratio in respect of the mechanical strengths. Accordingly, the method of multiple-layered resist is recently under studies which is considered to achieve a high aspect ratio with less difficulty in a high dimensional precision and pattern formation by this multiple-layered resist method is now indispensable because, when a plural numbers of lithographic steps are conducted to form a multilayered circuit in order to obtain a particularly high degree of integration, ruggedness appears on the surface thereof.

While, as the resist materials used in the multiple-layered resist methods, there are known those having a bilayered structure consisting of the upper layer of a positive-working resist layer and the lower layer of an organic resin layer and those having a three-layered structure by providing a thin metallic film layer as an intermediate layer between these upper layer and lower layer, thinness of the positive-working resist layer is accomplished in each of them by ensuring a requisite thickness with the organic layer.

While these resist materials are employed for engraving a pattern in the substrate by plasma etching with a mask pattern-formed of the positive-working resist layer as the upper layer, film thickness reduction is caused in the course of the plasma etching when the positive-working resist layer as of the upper layer lacks etching resistance so that the role as the mask pattern cannot be fully played to give a reason for the three-layered structure by providing the layer of a thin metallic film layer as an intermediate. Accordingly, if the positive-working resist layer as the upper layer had an etching resistance high enough even with a small thickness, it would be of no use to have a three-layered structure by undertaking complicated working steps but a bilayered structure could be employed.

Therefore, studies were undertaken for a positive-working resist composition having high resistance against oxygen plasma and excellent cross sectional profile of the pattern. Proposals were made heretofore for a positive-working resist composition using an alkali-soluble ladder silicone polymer represented by the general formula, 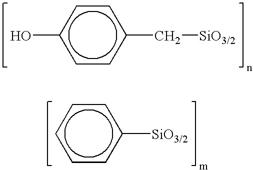
[n and m in the formula are each 0 or a positive integer which satisfy the relationship of 0.5≦n and (n+m)≦0.7]as an alkali-soluble resin (see patent publication 1) and a chemical-amplification type positive-working resist composition using a polymer introduced by a residue of a silicone-containing compound having polycyclic hydrocarbon groups together with a residue of an alicyclic compound and a residue of diacrylate compound (see patent publication 2).

However, these chemical-amplification type positive-working resist compositions are not necessarily satisfactory in respect of cross sectional profile of a pattern, focusing depth latitude and the line edge roughness along with difficulties in obtaining the starting materials so that a silicone-based positive-working resist composition which has more excellent properties is desired.

Patent Publication 1

Official publication of Japanese Patent No. 2567984 (Claims and elsewhere)

Patent Publication 2

Official publication of Japanese Patent Kokai No. 2001-233920 (Claims and elsewhere)

### DISCLOSURE OF THE INVENTION

The present invention has been completed with an object to provide a chemical-amplification type silicone-based positive-working resist composition capable of being prepared by a simple means using compounds having good availability as the starting materials and capable of forming, by a bilayered resist material using same, a fine pattern having high pattern resolution, high aspect ratio, an excellent cross sectional profile and little line edge roughness and the bilayered resist material using same as well as a ladder-type silicone copolymer used therein.

The inventors have continued extensive investigations in order to develop a chemical-amplification type silicone-based positive-working resist composition for a bilayered resist material capable of decreasing line edge roughness as well as an excellent cross sectional profile of the resist pattern and wide focusing depth latitude and, as a result, have arrived at a discovery that the object can be accomplished by using an alkali-soluble ladder-type silicone copolymer which contains three kinds of silsesquioxane units including (hydroxyphenylalkyl)silsesquioxane units, (alkoxyphenylalkyl)silsesquioxane units and alkyl- or phenylsilsesquioxane units leading to completion of the present invention on the base of this discovery.

Namely, the present invention provides a chemical-amplification type silicone-based positive-working resist composition characterized, in a chemical-amplification type positive-working resist composition containing (A) an alkali-soluble resin and (B) a photoacid-generating agent, a ladder-type silicone copolymer containing (a₁) (hydroxyphenylalkyl)silsesquioxane units, (a₂) (alkoxyphenylalkyl)silsesquioxane units and (a₃) alkyl- or phenylsilsesquioxane units is used as the alkali-soluble resin (A), and a bilayered resist material characterized in that an organic layer is provided on a substrate and a layer of the above-mentioned chemical-amplification type silicone-based positive-working resist composition is formed thereon as well as a novel ladder-type silicone copolymer which contains (hydroxyphenylalkyl)silsesquioxane units, (alkoxyphenylalkyl)silsesquioxane units and phenylsilsesquioxane units used therein.

### BEST MODE FOR CARRYING OUT THE INVENTION

The chemical-amplification type silicone-based positive-working resist composition of the present invention contains (A) an alkali-soluble resin and (B) a photoacid-generating agent as the essential ingredients.

The component (A) is a ladder-type silicone copolymer and it is necessary to use a ladder-type silicone copolymer containing (a₁) (hydroxyphenylalkyl)silsesquioxane units or, namely, the constituent units represented by the general formula, 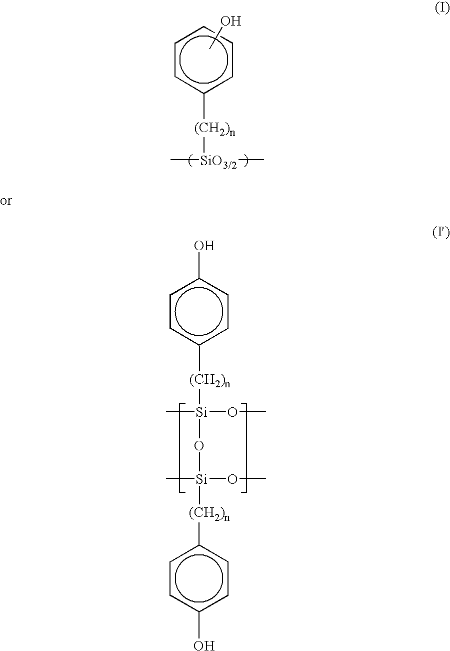
(n in the formula is a positive integer of 1-3), (a₂) (alkoxyphenylalkyl)silsesquioxane units or, namely, the constituent units represented by the general formula, 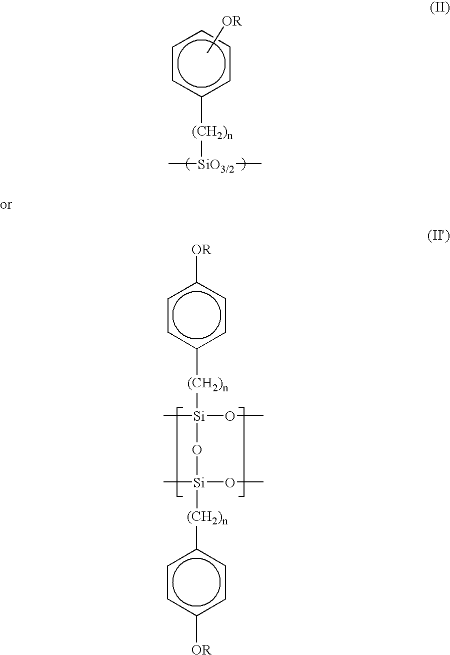
(in the formula, R is a straightly linear or branched lower alkyl group having 1-4 carbon atoms and n is a positive integer of 1-3) and (a₃) alkyl- or phenylsilsesquioxane units or, namely, the constituent units represented by the formula, 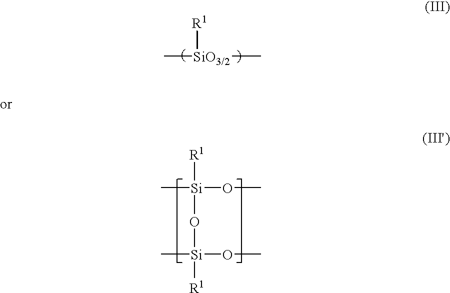
(R¹ in the formula is a straightly linear alkyl group having 1-20 carbon atoms, a branched alkyl group having 2-20 carbon atoms, an alicyclic, a cyclic or a polycyclic alkyl group having 5-20 carbon atoms or phenyl group).

R in the above given general formula (II) or (II′) is a lower alkyl group of which a methyl group is most preferable. As to R¹ in this formula (III) or (III′), a lower alkyl group having 1-5 carbon atoms, cycloalkyl group having 5-6 carbon atoms or phenyl group is preferable in respect of easy adjustment of the k value (extinction coefficient) of the coating film. Further, the bonding position of the —OH group and —OR group in the above given general formulas (I) and (II) can be any of o-position, m-position and p-position of which the p-position is industrially preferable. Furthermore, (a₁), (a₂) and (a₃) units can be usually represented by the above given general formulas (I), (II) and (III) or (I′), (II′) and (III′). It is possible to contain known copolymerizable units other than these units in such a range to accomplish the object of the present invention.

Preferable ladder-type silicone copolymers are those having a mass-average molecular weight (making reference to polystyrenes) in the range of 1500-30000 of which those having 3000-20000 are more preferable. The molecular weight dispersion is preferably in the range of 1.0-5.0 of which 1.2-3.0 is more preferable.

The compounding proportion of these constituent units can be selected within the range of 10-70% by moles or, preferably, 20-55% by moles of the units (a₁), 5-50% by moles or, preferably, 10-40% by moles of the units (a₂) and 10-60% by moles or, preferably, 20-40% by moles of the units (a₃).

The units (a₂) among them serve to adjust the alkali-solubility thereby to reduce the film thickness reduction and to prevent appearance of roundness in the cross sectional profile of the resist pattern. Advantageously, the same can be introduced easily by suppressing the degree of dissociation of the alkoxy groups because they are the same as the (alkoxyphenylalkyl)silsesquioxane units to serve as the starting material of the (hydroxyphenylalkyl)silsesquioxane units.

It is preferable in the chemical-amplification type silicone-based positive-working resist composition of the present invention that the dissolving rate in alkali is adjusted to be 0.05-50 nm/s or, preferably, 5.0-30 nm/s by controlling the (a₂) units in the component (A). The mass-average molecular weight of the component (A) is preferably in the range of 1500-20000 making reference to polystyrenes.

The photoacid-generating agent as the component (B) is a compound capable of generating an acid by irradiation with light which is conventionally used as a heretofore known ingredient in chemical-amplification type positive-working resist compositions. In the present invention, it is used by appropriately selecting from those heretofore known in this way, while an onium salt or a diazomethane compound is particularly preferable. It is preferable to use as a combination of an onium salt and diazomethane. It is more preferable to use an onium salt in combination with 10-80% by mass of the diazomethane compound based on the mass thereof due to a decrease in the line edge roughness at contact holes.

Preferable photoacid-generating agents as the component (B) in the chemical-amplification type silicone-based positive-working resist composition of the present invention are exemplified by onium salts such as diphenyliodonium trifluoromethanesulfonate or nonafluorobutanesulfonate, bis(4-tert-butylphenyl)iodonium trifluoromethanesulfonate or nonafluorobutanesulfonate, triphenylsulfonium trifluoromethanesulfonate or nonafluorobutanesulfonate, tri(4-methylphenyl)sulfonium trifluoromethanesulfonate or nonafluorobutanesulfonate and the like, diazomethane compounds such as bis(p-toluenesulfonyl)diazomethane, bis(1,1-dimethylethylsulfonyl)diazomethane, bis(isopropylsulfonyl)diazomethane, bis(cyclohexylsulfonyl)diazomethane, bis(2,4-dimethylphenylsulfonyl)diazomethane and the like. Particularly preferable among them are triphenylsulfonium trifluoromethanesulfonate and triphenylsulfonium nonafluorobutanesulfonate.

This photoacid-generating agent as the component (B) can be used singly or can be used as a combination of two kinds or more. The compounding amount is selected in the range of, usually, 0.5-30 parts by mass or, preferably, 1-20 parts by mass per 100 parts by mass of the above-mentioned component (A). When the compounding amount of the photoacid-generating agent is smaller than 0.5 part by mass, image formation can hardly be accomplished while, when in excess over 30 parts by mass, a decrease is greatly caused in the heat resistance of the resist resulting in difficulties in the formation of an orthogonal cross sectional profile.

The chemical-amplification type silicone-based positive-working resist composition of the present invention can be admixed according to need with a dissolution inhibitor as the component (C) in addition to the above-mentioned components (A) and (B) as the essential ingredients. A phenolic compound having a phenolic hydroxyl group protected by an acid-dissociable group or a carboxylic compound having a carboxyl group protected by an acid-dissociable group can be used as the dissolution inhibitor.

Among them, the phenolic compound having a phenolic hydroxyl group protected by an acid-dissociable group includes polyphenolic compounds having 3-5 phenolic groups such as, for example, triphenylmethane compounds and bis(phenylmethyl)diphenylmethane compounds each having hydroxyl groups as nucleus substituting groups. Binuclear to hexanuclear compounds obtained by condensation of phenolic compounds selected from phenol, m-cresol and 2,5-xylenol with formalin can also be used.

And, the carboxylic compound having a carboxylic group protected by an acid-dissociable group includes biphenylcarboxylic acid, naphthalene(di)carboxylic acid, benzoylbenzoic acid, anthracene carboxylic acid and the like.

The acid-dissociable group protecting the hydroxyl group in the phenolic compound or the carboxylic group in the carboxylic compound is exemplified by tertiary-butyloxycarbonyl groups such as tert-butyloxycarbonyl group and tert-amyloxycarbonyl group, tertiary-alkyl groups such as tert-butyl group and tert-amyl group, tertiary-alkoxycarbonylalkyl groups such as tert-butyloxycarbonylmethyl group and tert-amyloxycarbonylmethyl group, cyclic ether groups such as tetrahydropyranyl group and tetrahydrofuranyl group and the like. And, suitable compounds as such a dissolution inhibitor are those from tetranuclear compounds obtained by condensation of a 2,5-xylenol-formalin condensate protected by tert-alkoxycarbonylalkyl groups.

These dissolution inhibitors can be used singly or can be used as a combination of two kinds or more. These dissolution inhibitors can be used within the range of 0.5-40 parts by mass or, preferably, 10-30 parts by mass per 100 parts by mass of the alkali-soluble resin as the component (A). When the amount is smaller than 0.5 part by mass, sufficient dissolution inhibitive effects can not be obtained while, when in excess over 40 parts by mass, deterioration is caused in the cross sectional profile of a pattern or poor photolithographic characteristic is resulted.

In the chemical-amplification type silicone-based positive-working resist composition of the present invention, according to desire, an amine and/or an organic acid can be further compounded as a quencher (D). The amine is compounded in order to prevent deterioration of the resist pattern with time by standing from light-exposure to post-exposure baking treatment and the organic acid is compounded in order to prevent crease of sensitivity due to compounding of the amine.

As the above-mentioned amines, aliphatic amines such as trimethylamine, diethylamine, triethylamine, di-n-propylamine, tri-n-propylamine, triisopropylamine, dibutylamine, tributylamine, tripentylamine, diethanolamine, triethanolamine, diisopropanolamine and triisopropanolamine, aromatic amines such as benzylamine, aniline, N-methylaniline, N,N-dimethylaniline, o-methylaniline, m-methylaniline, p-methylaniline, N,N-diethylaniline, diphenylamine and di-p-tolylamine, heterocyclic amines such as pyridine, o-methylpyridine, o-ethylpyridine, 2,3-dimethylpyridine, 4-ehtyl-2-methylpyridine and 3-ethyl-4-methylpyridine and the like can be named. These amines can be used singly or can be used as a combination of two kinds or more. Among them, trialkanolamines are particularly preferable of which triethanolamine is the most preferable.

Organic phosphonic acids or carboxylic acids can be used as the above-mentioned organic acid and such an organic phosphonic acid is exemplified by phenylphosphonic acid and, as the carboxylic acid, aliphatic carboxylic acids such as acetic acid, citric acid, succinic acid, malonic acid, maleic acid and the like and aromatic carboxylic acids such as benzoic acid, salicylic acid and the like can be used. Particularly preferable ones include phenylphosphonic acid and salicylic acid of which phenylphosphonic acid is the most preferable. These organic acids can be used singly or can be used as a combination of two kinds or more.

Such a quencher can be used within the range of 0.01-5 parts by mass or, preferably, 0.1-1 part by mass per 100 parts by mass of the alkali-soluble resin as the component (A). When the amount thereof is too small, deterioration of the resist pattern by standing after light-exposure cannot be prevented while, when too large, the throughput decreases in the lithographic procedure. When the amine or a combination of the amine and the organic acid is used, stability with time after light-exposure can be further improved. It is particularly preferable to use a combination of triethanolamine as the amine and phenylphbsphonic acid or salicylic acid as the organic acid.

When used, the chemical-amplification type silicone-based positive-working resist composition of the present invention is used in the form of a solution prepared by dissolving in a suitable solvent. Examples of the solvents used in this case include ketones such as acetone, methyl ethyl ketone, cyclohexanone, methyl isoamyl ketone and the like, polyhydric alcohols and derivatives thereof such as ethyleneglycol, ethyleneglycol monoacetate, diethyleneglycol or diethyleneglycol monoacetate as well as monomethyl ethers, monoethyl ethers, monopropyl ethers, monobutyl ethers or monophenyl ethers thereof and the like, cyclic ethers such as dioxane and esters such as methyl lactate, ethyl lactate, methyl acetate, ethyl acetate, butyl acetate, methyl pyruvate, ethyl pyruvate and the like. These can be used singly or can be used as a mixture of two kinds or more.

The chemical-amplification type silicone-based positive-working resist composition of the present invention can be admixed according to desire further with additives having miscibility such as, for example, those under conventional use including sensitizers, auxiliary resins plasticizers, stabilizers, coloring agents to obtain a further improved visibility of the developed image and the like.

In the next place, a bilayered resist material using the chemical-amplification type silicone-based positive-working resist composition of the present invention is prepared in such a way that an organic layer is first provided on a substrate to have the same as the lower layer and a layer of the chemical-amplification type silicone-based positive-working resist composition is formed thereon. The substrate used in this case can be freely selected from materials conventionally used as a material for substrate of semiconductor devices without any particular limitations.

For the organic layer formed on the substrate as the lower layer, almost all kinds of organic materials can be used provided that the material is susceptible to dry etching with an oxygen plasma. Those conventionally used include organic photoresists, poly(methyl methacrylate), copolymers of methyl methacrylate and methacrylic acid, imide-based resins and the like but novolak resins and novolak resins with introduction of 1,2-quinonediazido groups are preferred.

A photosensitive layer is formed by applying a solution of the chemical-amplification type silicone-based positive-working resist composition of the present invention onto the organic layer formed in this way by a conventional method. Thicknesses of the respective layers after drying in this case can be selected in the range of 200-800 nm or, preferably, 300-600 nm for the organic layer and 50-200 nm or, preferably, 80-150 nm for the photosensitive layer.

To show an example of the method for the preparation of a desired resist pattern using this bilayered resist material, the lower layer consisting of an organic layer is first formed on a substrate according to a known method and then a solution of the inventive composition is applied thereon by using, for example, a spinner followed by drying and the same is subjected to selective irradiation through a desired photomask with actinic rays suitable for solubilizing the same including, for example, actinic rays emitted from a light source such as low-pressure mercury lamps, high-pressure mercury lamps, ultrahigh-pressure mercury lamps, arc lamps, xenon lamps and the like and excimer laser beams, or subjected to irradiation according to the minifying projection light-exposure method. In the next place, the areas solubilized by the light-exposure of the resist film are dissolved and removed away with a developer solution which is, for example, an aqueous alkaline solution such as a 1-5% by mass aqueous solution of sodium hydroxide, an aqueous solution of tetramethylammonium hydroxide, an aqueous solution of trimethyl(2-hydroxyethyl)ammonium hydroxide and the like to form a resist pattern on the substrate. In the next place, the organic layer exposed on the substrate is subjected to dry etching by oxygen gas or, for example, to etching according to a plasma etching method, reactive ion etching method and the like so as to obtain a pattern having fidelity to the mask pattern.

The wavelength of the light used for the light-exposure is not particularly limited and radiations such as ArF excimer lasers, KrF excimer lasers, F₂ excimer lasers, EUV (extreme ultraviolet light), VUV (vacuum ultraviolet light), EB (electron beams), X-rays, soft X-rays and the like can be used. The present invention is particularly effective for KrF excimer lasers.

The ladder-type silicone copolymer as the component (A) used in the resist composition and bilayered resist material of the present invention is suitable because of the etching resistance and alkali-solubility so that, when used as the resinous ingredient as a base material of the resist composition, it is preferable since the solubility thereof can be adjusted to fall within the desired range.

The said ladder-type silicone copolymer can be synthesized according to a method known per se such as, for example, the method of Preparation Example 1 described in official publication of Japanese Patent No. 2567984.

Among the ladder-type silicone copolymers as the component (A), copolymers containing (hydroxyphenylalkyl)silsesquioxane units, (alkoxyphenylalkyl)silsesquioxane units and phenylsilsesquioxane units are novel compounds not described in any literatures. A copolymer consisting of 10-70% by moles of the (hydroxyphenylalkyl)silsesquioxane units, 5-50% by moles of the (alkoxyphenylalkyl)silsesquioxane units and 10-60% by moles of the phenylsilsesquioxane units is preferable for use in the resist composition of the present invention of which a copolymer having a mass-average molecular weight of 1500-30000 with a molecular weight dispersion in the range of 1.0-5.0 is particularly satisfactory.

In the following, the present invention is described in more details by way of examples although the present invention is never limited by these examples in any way.

Meanwhile, the properties in the respective Examples were measured by the following methods.

(1) Sensitivity:

The resist composition was applied by using a spinner onto a silicon wafer provided with an organic antireflection film (a product of Brewer Science, Inc., product name “DUV-44”) of 65 nm and the same was subjected to drying at 100° C. for 90 seconds on a hot plate to obtain a resist film of 0.5 μm film thickness. By using a minifying projection light-exposure machine (manufactured by Nikon Corp., product name “NSR-203B”, NA=0.60), this film was light-exposed with KrF excimer laser beams in doses with additions of each 10 J/cm² increment followed by post-exposure baking (PEB) at 110° C. for 90 seconds, developed with a 2.38% by mass aqueous solution of tetramethylammonium hydroxide at 23° C. taking 60 seconds, water-rinsed for 30 seconds and dried and the minimum light-exposure time by which the film thickness after development in the light-exposed areas was 0 was determined in the unit of mJ/cm² (amount of energy) and taken as the sensitivity.

(2) Cross Sectional Profile of Resist Pattern:

A cross sectional profile of a resist pattern of 140 nm line-and-space obtained by the same procedure as in (1) above was evaluated on a SEM (scanning electron microscope) photograph.

A: those having an angle of 85-90° between the substrate and the resist pattern

B: those having an angle of 70-85° between the substrate and the resist pattern

C: those having an angle smaller than 70° between the substrate and the resist pattern

(3) Focusing Depth Latitude:

By undertaking the same procedure as in (1) above, measurement was made for the focusing depth latitude which afforded formation of the 140 nm line-and-space pattern with a good profile.

(4) Dissolving Rate:

The amount of film thickness reduction per one second (nm/s) was determined when a substrate having a resist film was dipped in a 2.38% by mass aqueous solution of tetramethylammonium hydroxide at 23° C.

(5) Line Edge Roughness

Evaluation was made by observation of a 140 nm line-and-space pattern formed in the same procedure as in (1) above on a scanning electron microscopic photograph rating as A when almost no roughness (depressions and protrusions on the resist line) was found, as B when small roughness was found and as C when large roughness was found.

(6) Pattern Resolution

The critical pattern resolution was shown at the optimum light-exposure dose by the same procedure as in (1) above.

The abbreviations for the photoacid-generating agents, dissolution inhibitors and solvents used in the respective Examples have the following meanings.

Photoacid-generating agent TPS salt: triphenylsulfonium trifluoromethanesulfonate expressed by the formula,

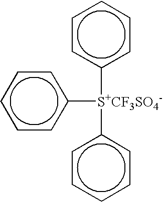

Dissolution inhibitor DI22: a polynuclear phenolic compound expressed by the formula,

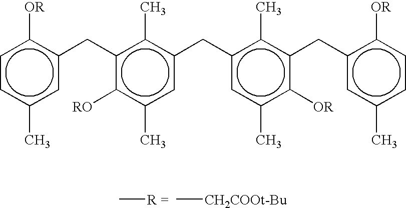

Solvent EL: ethyl lactate

### REFERENCE EXAMPLE 1

Into a 500 ml three-necked flask equipped with a stirrer, reflux condenser, dropping funnel and thermometer were introduced 1.00 mole (84.0 g) of sodium hydrogencarbonate and 400 ml of water and then a solution by dissolving 0.32 mole (81.8 g) of p-methoxybenzyl trichlorosilane and 0.18 mole (38.1 g) of phenyl trichlorosilane in 100 ml of diethyl ether was added dropwise through the dropping funnel under agitation over 2 hours followed by heating for 1 hour under reflux. After completion of the reaction, the reaction product was extracted with diethyl ether and the extractant solution was freed from diethyl ether by distillation under reduced pressure.

The thus obtained hydrolysis product was admixed with 0.33 g of a 10% by mass aqueous solution of potassium hydroxide and heated for 2 hours at 200° C. to prepare a copolymer A₁ consisting of 64% by moles of p-methoxybenzyl silsesquioxane units and 36% by moles of phenyl silsesquioxane units. The analytical results of the copolymer A₁ by the proton NMR, infrared absorption spectrum and GPC (gel permeation chromatography) are shown below.

¹H-NMR (DMSO-d₆): δ=2.70 ppm (—CH₂—); 3.50 ppm (—OCH₃); and 6.00-7.50 ppm (benzene ring);

IR (cm⁻¹): ν=1178 (—OCH₃); 1244 and 1039 (—SiO—);

Mass-average molecular weight (Mw): 7500; and dispersion (Mw/Mn):1.8 In the next place, this copolymer A₁ was added to a solution prepared by dissolving 150 ml of acetonitrile together with 0.4 mole (80.0 g) of trimethylsilyl iodide and agitated for 24 hours under reflux and then 50 ml of water were added thereto followed by agitation for further 12 hours under reflux to effect the reaction. After cooling, reduction of free iodine was undertaken with an aqueous solution of sodium hydrogensulfite followed by separation of the organic layer which was freed from the solvent by distillation. The residue was subjected to reprecipitation with acetone and n-hexane followed by drying by heating under reduced pressure to prepare a copolymer A₂ consisting of 64% by moles of (p-hydroxybenzyl)silsesquioxane units and 36% by moles of phenyl silsesquioxane units. The analytical results of the copolymer A₂ by the proton NMR, infrared absorption spectrum and GPC (gel permeation chromatography) are shown below.

¹H-NMR (DMSO-d₆): δ=2.70 ppm (—CH₂—); 6.00-7.50 ppm (benzene ring); and 8.90 ppm (—OH);

IR (cm⁻¹): ν=3300 (—OH); 1244; and 1047 (—SiO—);

Mass-average molecular weight (Mw): 7000; and dispersion (Mw/Mn): 1.8

### REFERENCE EXAMPLE 2

A copolymer A₃ consisting of 55% by moles of (p-hydroxybenzyl)silsesquioxane units and 45% by moles of phenylsilsesquioxane units was prepared in the same manner as in Reference Example 1 except that, in Reference Example 1, the used amounts of p-methoxybenzyl trichlorosilane and phenyl trichlorosilane were each changed to 0.275 mole (70.3 g) and 0.225 mole (47.6 g). The analytical results of the copolymer A₃ by the proton NMR, infrared absorption spectrum and GPC (gel permeation chromatography) are shown below.

¹H-NMR (DMSO-d₆): δ=2.70 ppm (—CH₂—); 6.00-7.50 ppm (benzene ring); and 8.90 ppm (—OH);

IR (cm⁻¹): ν=3300 (—OH); 1244; and 1047 (—SiO—);

Mass-average molecular weight (Mw): 7000; and dispersion (Mw/Mn): 1.8

### EXAMPLE 1

The same procedure as in Reference Example 1 excepting for the adjustment of the amount of trimethylsilyl iodide was undertaken for the preparation of three kinds of copolymers (A₄), (A₅) and (A₆) in which the molar ratios of the p-hydroxyphenylbenzyl silsesquioxane units, p-methoxybenzyl silsesquioxane units and phenyl silsesquioxane units were 49:15:36 (A₄), 25:39:36 (A₅) and 44:20:36 (A₆) by conducting partial hydrolysis of the p-methoxy groups in the copolymer A₁ prepared in Reference Example 1. Incidentally, the amounts of the trimethylsilyl iodide for (A₄), (A₅) and (A₆) were changed to 0.383 mole, 0.196 mole and 0.344 mole, respectively, so that the yields therein were 38.9 g, 39.8 g and 39.1 g, respectively. The analytical results of (A₄), (A₅) and (A₆) by the proton NMR, infrared absorption spectra and GPC (gel permeation chromatography) are shown below.

¹H-NMR (DMSO-d₆): δ=2.70 ppm (—CH₂—); 3.50 ppm (—OCH₃); 6.00-7.50 ppm (benzene ring) and 8.90 ppm (—OH);

IR (cm⁻¹): ν=3300 (—OH); 1178 (—OCH₃); 1244 and 1047 (—SiO—);

Mass-average molecular weight (Mw): 7000; and dispersion (Mw/Mn): 1.8

### COMPARATIVE EXAMPLE 1

A solution of a chemical-amplification type silicone-based positive-working resist composition was prepared by dissolving, in 1730 parts by mass of the solvent EL, per 100 parts by mass of the copolymer A₁ prepared in Reference Example 1, 3.0 parts by mass of the photoacid-generating agent TPS salt, 27.0 parts by mass of the dissolution inhibitor DI22 and 0.16 part by mass of phenylphosphonic acid and 0.15 part by mass of triethanolamine as a quencher.

### COMPARATIVE EXAMPLE 2

A solution of a chemical-amplification type silicone-based positive-working resist composition was prepared by dissolving, in 1730 parts by mass of the solvent EL, 3.0 parts by mass of the photoacid-generating agent TPS salt, 27.0 parts by mass of the dissolution inhibitor DI22 and 0.15 part by mass of triethanolamine as a quencher per 100 parts by mass of the copolymer A₂ obtained in Reference Example 1. Incidentally, the dissolving rate of A₂ was 130.0 nm/s.

### COMPARATIVE EXAMPLE 3

A solution of a chemical-amplification type silicone-based positive-working resist composition was prepared by dissolving, in 1730 parts by mass of the solvent EL, 3.0 parts by mass of the photoacid-generating agent TPS salt, 27.0 parts by mass of the dissolution inhibitor DI22 and 0.15 part by mass of tributylamine as a quencher per 100 parts by mass of the copolymer A₃ obtained in Reference Example 2. Incidentally, the dissolving rate of A₃ was 82.0 nm/s.

### EXAMPLE 2

A solution of a chemical-amplification type silicone-based positive-working resist composition was prepared by dissolving, in 1730 parts by mass of the solvent EL, 3.0 parts by mass of the photoacid-generating agent TPS salt, 27.0 parts by mass of the dissolution inhibitor DI22 and 0.15 part by mass of triethanolamine and 0.16 part by mass of phenylphosphonic acid as a quencher per 100 parts by mass of the copolymer A₄ obtained in Example 1. Incidentally, the dissolving rate of A₄ was 4.56 nm/s.

### EXAMPLE 3

A solution of a chemical-amplification type silicone-based positive-working resist composition was prepared in the same manner as in Example 2 by using the copolymer A₅ obtained in Example 1. Incidentally, the dissolving rate of A₅ was 0.073 nm/s.

### EXAMPLE 4

A solution of a chemical-amplification type silicone-based positive-working resist composition was prepared in the same manner as in Example 2 by using the copolymer A₆ obtained in Example 1. Incidentally, the dissolving rate of A₆ was 20.46 nm/s.

### APPLICATION EXAMPLE

An organic layer was provided by applying a novolak resin (product of Tokyo Ohka Kogyo Co., product name “TBLC-100”) in a thickness after drying of 600 nm on a 75 mm silicone wafer followed by heating at 230° C. for 90 seconds. Nextly, solutions of chemical-amplification type silicone-based positive-working resist compositions having the compositions obtained in Examples 2, 3 and 4 and Comparative Examples 1, 2 and 3 as shown in Table 1 were uniformly applied thereon in a film thickness after drying of 130 nm followed by drying on a hot plate at 110° C. for 90 seconds. Nextly, by using a minifying projection light-exposure machine (manufactured by Nikon Corp., product name of “NSR-203B”), light-exposure was undertaken with KrF excimer laser beams followed by development with a 2.38% by mass aqueous solution of tetramethylammonium hydroxide at 23° C. for 30 seconds. Then, the thus obtained resist pattern was subjected to reactive ion etching by using an etching apparatus (manufactured by Tokyo Ohka Kogyo Co., “GP2”) under the condition of the pressure of 0.4 Pa, the flow rate of oxygen gas of 20 ml/min., the RF output power of 1000 W and the processing temperature of 25° C. The properties of the thus obtained bilayered resist materials are shown in Table 2.

TABLE 1

| | | Sample No. | | | | | |
|---|---|---|---|---|---|---|---|
| | | 1 | 2 | 3 | 4 | 5 | 6 |
| Type of coating | | CE1 | CE2 | CE3 | E2 | E3 | E4 |
| solution* | | | | | | | |
| Resin (A) used | | A₁ | A₂ | A₃ | A₄ | A₅ | A₆ |
| Dissolving rate of | | 0.0 | 130.0 | 82.0 | 4.56 | 0.073 | 20.46 |
| resin (nm/s) | | | | | | | |
| Composition | a₁ | 0 | 64 | 55 | 49 | 25 | 44 |
| of resin | a₂ | 64 | 0 | 0 | 15 | 39 | 20 |
| (% by moles) | a₃ | 36 | 36 | 45 | 36 | 36 | 36 |
| Used amount | | 100 | 100 | 100 | 100 | 100 | 100 |
| of resin | | | | | | | |
| (parts by mass) | | | | | | | |
| Photo- | Type | TPS | TPS | TPS | TPS | TPS | TPS |
| acid | | salt | salt | salt | salt | salt | salt |
| generating | Used | 3.0 | 3.0 | 3.0 | 3.0 | 3.0 | 3.0 |
| agent | amount | | | | | | |
| | (parts by | | | | | | |
| | mass) | | | | | | |
| Dissolution | Type | DI22 | DI22 | DI22 | DI22 | DI22 | DI22 |
| inhibittor | Used | 27.0 | 27.0 | 27.0 | 27.0 | 27.0 | 27.0 |
| | amount | | | | | | |
| | (parts by | | | | | | |
| | mass) | | | | | | |
| Quencher | Type | Trietha- | Tri- | Tri- | Trietha- | Trietha- | Trietha- |
| | (used | nolamine | etha- | butyl- | nolamine | nolamine | nolamine |
| | amount, | (0.15) | nol- | amine | (0.15) | (0.15) | (0.15) |
| | parts by | Phenyl- | amine | (0.15) | Phenyl- | Phenyl- | Phenyl- |
| | mass) | phospho- | (0.15) | | phospho- | phospho- | phospho- |
| | | nic acid | | | nic acid | nic acid | nic acid |
| | | (0.16) | | | (0.16) | (0.16) | (0.16) |
| Solvent | Type | EL | EL | EL | EL | EL | EL |
| | Used | 1730 | 1730 | 1730 | 1730 | 1730 | 1730 |
| | amount | | | | | | |
| | (parts by | | | | | | |
| | mass) | | | | | | |

*CE: Comparative Example; E: Example

TABLE 2

| | | Sample No. | | | | | |
|---|---|---|---|---|---|---|---|
| | | 1 | 2 | 3 | 4 | 5 | 6 |
| Properties | Sensitivity | 17 | 13 | 14 | 21 | 26 | 22 |
| | (mJ/cm²) | | | | | | |
| | Cross sectional | C | C | C | A | A | A |
| | profile of resist | | | | | | |
| | pattern | | | | | | |
| | Focusing depth | 0.2 | 0.4 | 0.45 | 0.7 | 0.6 | 0.75 |
| | latitude (μm) | | | | | | |
| | Line edge | C | B | B | A | A | A |
| | roughness | | | | | | |
| | Pattern resolution | 0.14 | 0.13 | 0.12 | 0.12 | 0.12 | 0.12 |
| | (μm) | | | | | | |

### INDUSTRIAL UTILIZABILITY

The chemical-amplification type silicone-based positive-working resist composition of the present invention has, when used for a bilayered resist material, high photosensitivity, high pattern resolution and an excellent cross sectional profile and gives a pattern with little line edge roughness so that it is suitable for use of a chemical-amplification type resist material corresponding -to radiations having a short wavelength such as KrF, ArF or F₂ excimer laser beams and others for which fine works not exceeding 0.20 nm are required.

1. A chemical-amplification type silicone-based positive-working resist composition characterized in that, in a chemical-amplification type positive-working resist composition containing (A) an alkali-soluble resin and (B) a photoacid-generating agent,
a ladder-type silicone copolymer containing (a₁) (hydroxyphenylalkyl)silsesquioxane units, (a₂) (alkoxyphenylalkyl)silsesquioxane units and (a₃) alkyl- or phenylsilsesquioxane units is used as the (A) alkali-soluble resin.

2. The chemical-amplification type silicone-based positive-working resist composition described in claim 1 in which the component (A) is a ladder-type silicone copolymer consisting of 10-70% by moles of the units (a₁), 5-50% by moles of the units (a₂) and 10-60% by moles of the units (a₃).

3. The chemical-amplification type silicone-based positive-working resist composition described in claim 1 in which the proportion of the units (a₂) is so adjusted that the dissolving rate in alkali be from 0.05 to 50 nm/s.

4. The chemical-amplification type silicone-based positive-working resist composition described in claim 1 in which the component (B) is an onium salt or a diazomethane compound.

5. The chemical-amplification type silicone-based positive-working resist composition described in claim 1 in which, in addition to the component (A) and component (B), a phenolic compound of which the phenolic hydroxyl group is protected by an acid-dissociable group or a carboxylic compound of which the carboxylic group is protected by an acid-dissociable group is compounded as a dissolution inhibitor (C), in a proportion of 0.5-40 parts by mass per 100 parts by mass of the component (A).

6. The chemical-amplification type silicone-based positive-working resist composition described in claim 1 in which, in addition to the component (A) and component (B) or the component (A), component (B) and component (C), an amine and/or an organic acid are/is compounded as a quencher (D) in a proportion of 0.01-5 parts by mass per 100 parts by mass of the component (A).

7. A bilayered resist material characterized in that an organic layer is provided on a substrate and a layer of the chemical-amplification type silicone-based positive-working resist composition described in claim 1 is formed thereon.

8. The bilayered resist material described in claim 7 in which the organic layer is a layer of a novolak resin or a layer of a novolak resin containing a 1,2-naphthoquinonediazido group.

9. The bilayered resist material described in claim 7 in which the organic layer has a thickness of 200-800 nm and the layer of the chemical-amplification type silicone-based positive-working resist composition has a thickness of 50-200 nm.

10. A ladder-type silicone copolymer which contains (hydroxyphenylalkyl)silsesquioxane units, (alkoxyphenylalkyl)silsesquioxane units and phenylsilsesquioxane units.

11. The ladder-type silicone copolymer described in claim 10 which consists of 10-70% by moles of the (hydroxyphenylalkyl)silsesquioxane units, 5-50% by moles of the (alkoxyphenylalkyl)silsesquioxane units and 10-60% by moles of the phenylsilsesquioxane units.

12. The ladder-type silicone copolymer described in claim 10 of which the dissolving rate in alkali is in the range of 0.05-50 nm/s.

13. The ladder-type silicone copolymer described in claim 10 of which the mass-average molecular weight is in the range of 1500-30000.

14. The ladder-type silicone copolymer described in claim 10 of which the molecular weight dispersion is in the range of 1.0-5.0.

15. A method of forming a patterned resist film on a substrate which comprises a step of selectively exposing the bilayered resist material described in claim 7 to actinic rays, and a step of dissolving away the portion of the resist film solubilized by the light-exposure with an aqueous alkali solution.
